(19) United States
(12) Patent Application Publication
(10) Pub. No.: US 2026/0190928 A1
(43) Pub. Date: Jul. 2, 2026

(54) CASSETTE HOLD DOWN WITH CONTACT ARMS

(71) Applicant: ENTEGRIS, INC., Billerica, MA (US)

(72) Inventors: Hang Khim Tan, Bukit Mertajam (MY); Mohamad Zakaria Abd Mutholib, Kulim (MY)

(21) Appl. No.: 19/427,237

(22) Filed: Dec. 19, 2025

Related U.S. Application Data
(60) Provisional application No. 63/739,454, filed on Dec. 27, 2024.

(51) Int. Cl. H10P 72/10

(52) U.S. Cl. CPC H10P 72/1912; H10P 72/1914; H10P 72/1921; H10P 72/1922

(57) ABSTRACT

A cassette hold down includes a frame and a plurality of contact arms that extend from the frame. The contact arms include a first contact arm and a second contact arm that extend in different directions from the frame. Each of the contact arms includes a fixed end affixed to the frame, a free end opposite to the fixed end, a cassette contact that extends from the free end in a first vertical direction, and a cassette contact that extends from the free end in a second vertical direction. A wafer container includes a pod, a door configured to close an open end of the pod, a wafer cassette, and a cassette hold down. In the assembled wafer container, a cassette contact of each contact arm of the frame abuts the wafer cassette in the wafer container.

### FIELD

This disclosure relates to wafer containers. More specifically, this disclosure relates to cassette hold downs used in wafer containers.

### BACKGROUND

Wafer containers can include a wafer cassette contained with an outer pod. The wafer cassette may move within the pod when the wafer container is moved or exposed to shocks such as being dropped, bumped, or the like. Such movement of the wafer cassette can lead to damage to the pod, cassette, or wafers, or lead to undesirable particle generation within the pod. The movement of the wafer cassette can also dislodge the wafer cassette from other retention features such as the supports on a door of the wafer container.

### SUMMARY

In an embodiment, a cassette hold down includes a frame and a plurality of contact arms extending from the frame. The contact arms include a first contact arm and a second contact arm that extend in different directions from the frame. Each of the contact arms includes a fixed end affixed to the frame, a free end opposite to the fixed end, a pod contact, and a cassette contact. The pod contact extends from the free end in a first vertical direction from a first side of the frame. The cassette contact extends from the free end in a second vertical direction from a second side of the frame opposite the first side.

In an embodiment, the frame includes a pair of longitudinal members that extend along a length of the frame. The contact arms extend between the pair of longitudinal members.

In an embodiment, the first contact arm extends from a first longitudinal member of the pair of longitudinal members. The second contact arm extends from a second longitudinal member of the pair of longitudinal members.

In an embodiment, the free end of the first contact arm is located closer to second longitudinal member than the first longitudinal member. The free end of the second contact arm is located closer to the first longitudinal member than the second longitudinal member.

In an embodiment, the contact arms are configured to be flexible allowing the free end of each of the contact arms to move independently from the frame.

In an embodiment, the contact arms extend side-by-side from the frame. The contact arms extend in alternating directions along a length of the frame.

In an embodiment, the different directions in which the first contact arm and the second contact arm extend from the frame are opposite directions.

In an embodiment, the contact arms include a third contact arm and a fourth contact arm that extend from the frame in the same different directions as the first contact arm and the second contact arm, respectively.

In an embodiment, the plurality of contact arms includes at least four contact arms.

In an embodiment, a cassette hold down includes a plurality of mounting bosses. Each of the mounting bosses extends from the frame in the first vertical direction from the first side of the frame.

In an embodiment, the mounting bosses are configured to mount the frame to an inside of a pod of a wafer container such that a gap is provided between the pod contact of each of the contact arms and the inside of the wafer container.

In an embodiment, the cassette contact of each of the contact arms includes a linear abutment surface configured to provide a linear contact point in abutting a wafer cassette.

In an embodiment, the cassette contact of each of the contact arms includes a wheel providing the linear abutment surface.

In an embodiment, a wafer container includes a pod, a door, a wafer cassette, and a cassette hold down. The pod includes one or more side walls, a closed end, an internal space defined by the one or more side walls and the closed end, and an open end. The door is configured to close the open end of the pod. The contact arms include a first contact arm and a second contact arm that extend in different directions from the frame. Each of the contact arms includes a fixed end affixed to the frame, a free end opposite to the fixed end, a pod contact, and a cassette contact. The pod contact extends from the free end in a first vertical direction from a first side of the frame. The cassette contact extends from the free end in a second vertical direction from a second side of the frame opposite the first side. When the wafer cassette and the cassette hold down are located in the internal space and the door is closing the open end, the cassette contact of each of the contact arms abuts the wafer cassette.

In an embodiment, when the wafer cassette and the cassette hold down are located in the internal space and the door is closing the open end, each of the contact arms has the pod contact spaced apart from an inner surface of the pod.

In an embodiment, the contact arms are configured to be flexible such that upward movement of the cassette pushes the pod contact of each of the contact arms against the inner surface of the pod and the contact arms limit the upward movement of the cassette within the internal space.

In an embodiment, the door includes supports for holding the wafer cassette within the internal space. The supports are configured to restrict lateral movement of the wafer cassette while allowing vertical movement of the wafer cassette.

In an embodiment, the wafer container includes a plurality of slots disposed in an inner surface of the pod. The cassette hold down includes a plurality of mounting bosses that each extend in the first vertical direction from the first side of the frame. The mounting bosses are configured to be disposed in the plurality of mounting holes to mount the cassette hold down to the inner surface of the pod.

In an embodiment, when the cassette hold is mounted to the inner surface of pod, the cassette contact of each of the contact arms is spaced apart from the inner surface of the pod.

### DRAWINGS

FIG. 1 shows an exploded view of an embodiment of a wafer container.

FIG. 2 shows a top perspective view of a cassette hold down of the wafer container in FIG. 1, according to an embodiment.

FIG. 3 shows a bottom perspective view of the cassette hold down in FIG. 2, according to an embodiment.

FIG. 4A shows a bottom view of a pod of the wafer container of FIG. 1, according to an embodiment.

FIG. 4B shows a bottom view of the pod of FIG. 4A mounted with the cassette hold down, according to an embodiment.

FIG. 5 shows a front sectional view of the wafer container of FIG. 1, according to an embodiment.

FIG. 6 shows the wafer container of FIG. 5 during a significant shock event, according to an embodiment.

FIG. 7 shows a side sectional view of the wafer container of FIG. 1, according to an embodiment.

FIG. 8 is a bottom perspective view of another embodiment of a cassette hold down.

Like numbers represent like features.

### DETAILED DESCRIPTION

This disclosure relates to wafer containers. More specifically, this disclosure relates to cassette holders used in wafer containers.

As used herein, “vertical direction” refers to a vertical direction when a component (e.g., the cassette hold down, the wafer container, etc.) is in an upright position. For example, a first vertical direction can refer to the upward direction and a second vertical direction can refer to the downward direction.

As used herein, a “shock event” refers to an event that applies a sudden force to the wafer container. For example, such events can include, but are not limited to, dropping, bumping, or the like to the wafer container. A substantial shock event applies sufficient force to the wafer cassette to cause at least one of the wafer cassette to become dislodged within the pod (e.g., moved so as to become dislodged from retaining support features on which the wafer cassette rests) or the wafer cassette to contact an inner surface of the pod, when a cassette hold down is not employed (e.g., moved to contact a sidewall or the closed end of the pod). In one non-limiting example, a substantial shock event can be a drop of the wafer container of at least one foot.

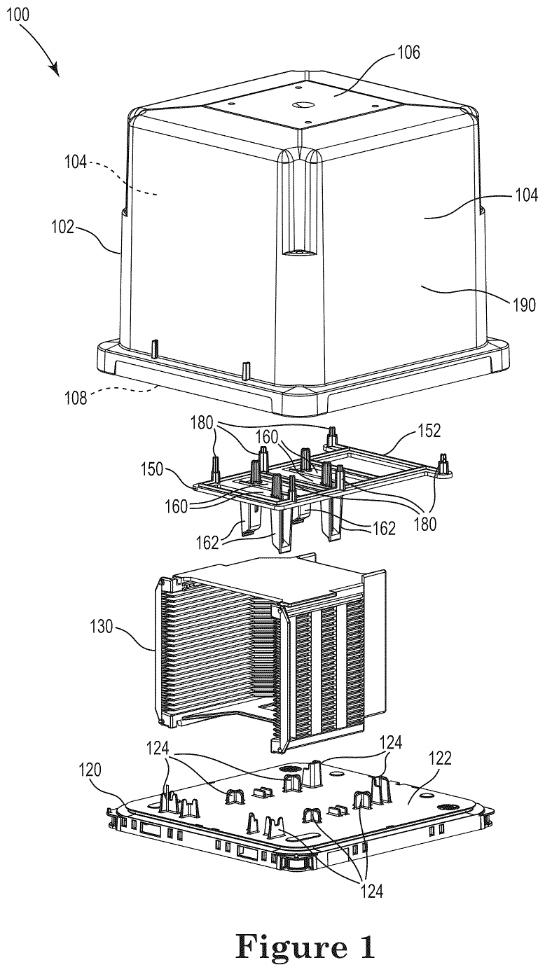

FIG. 1 shows an exploded view of an embodiment of a wafer container 100. The wafer container 100 includes a pod 102, a door 120, a wafer cassette 130, and a cassette hold down 150.

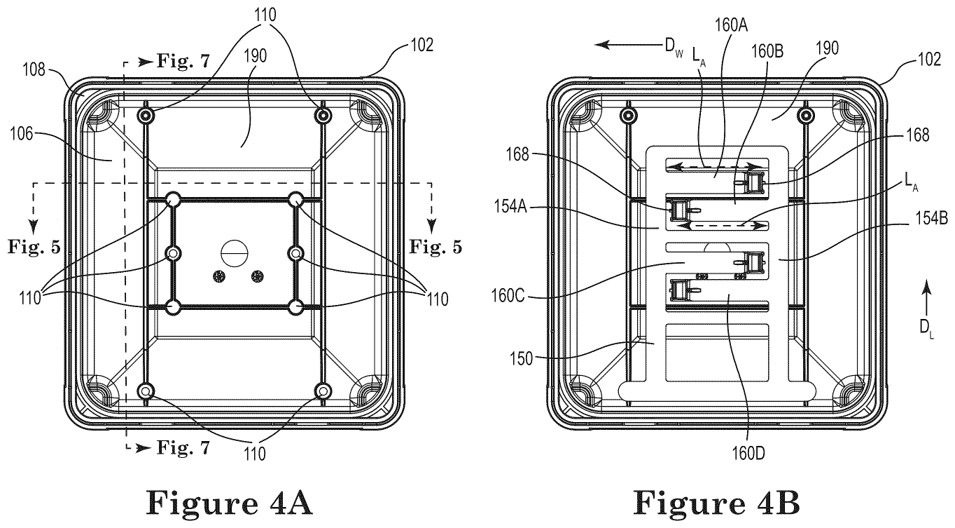

The wafer container 100 includes wafer cassette 130 contained within an internal space 190 (obscured in FIG. 1; e.g., shown in FIGS. 4A-7) defined by pod 102 and door 120. The wafer container 100 can be any such suitable container for holding one or more wafers, for example, a standard mechanical interface (SMIF) pod. The wafer container 100 can be used to hold one or more wafers, for example, during processing, transport, and/or storage of substrate wafers (e.g., semiconductor wafers).

The pod 102 defines the internal space 190 of the wafer container 100. The pod 102 includes one or more side walls 104, a closed end 106, and an open end 108 (e.g., obscured in FIG. 1; e.g., shown in FIGS. 4A-4B) opposite the closed end 106. The one or more side walls 104 extending between the closed end 106 and the open end 108. The one or more side walls 104 are not limited to a particular number or arrangement. The one or more side walls can be any arrangement and number of side walls that forms a continuous wall such that the side walls 104 and the closed end 106 define internal space 190 when the open end 108 is sealed by the door 120. For example, the pod 102 in an embodiment may have one side wall 104 that is a continuous, curved wall. For example, the pod 102 in the illustrated embodiment has four side walls 104, forming a rectangular or square shape.

The door 120 is configured to close the open end of pod 102. The door 120 attaches to the pod 102 to close the open end 108 of the pod 102. In some embodiments, the door 120 may be at least partially disposed in the open end 108 of the pod 102 when attached to the pod 102. When the door 120 is attached, the pod 102 and door 120 define the internal space 190 configured to accommodate the wafer cassette 130 and the cassette hold down 150. The door 120 can have a shape generally similar to that defined by the one or more side walls 104 of pod 102 (e.g., defined by the ends of the one or more side walls 104).

The door 120 can include one or more engagement features to attach the door 120 to pod 102 to enclose the internal space 190. The door 120 is configured for the wafer cassette 130 to rest on door 120 when the wafer container 100 is assembled. The wafer cassette 130 rests on a side 122 of the door 120 that faces the internal space 190 when the wafer container 100 is assembled. The door 120 can include supports 124 configured to hold the wafer cassette 130 within the internal space 190 when the wafer container 100 is assembled. For example, the side 122 of the door 120 includes the supports 124 extending from the surface thereof and the wafer cassette 130 rests on the supports 124. The supports 124 are configured to prevent lateral movement of the wafer cassette 130 within the internal space 190 of the wafer container 100.

The wafer cassette 130 is a container configured to accommodate one or more wafers (e.g., semiconductor wafers) in an internal space. The wafer cassette 130 can include one or more slots for holding the wafers. For example, the slots can be formed by a plurality of shelves provided on opposing walls of the wafer cassette 130. Each wafer can be held in a respective slot of the wafer cassette 130.

The cassette hold down 150 is mounted to the pod 102. In particular, the cassette hold down 150 is mounted to the inside of the pod 102. The cassette hold down 150 can include one or more mounting bosses 180. The pod 102 can include one or more mounting holes 110 (obscured in FIG. 1; e.g., shown in FIG. 4A) on an inner side of the closed end 106 that faces the internal space 190. The one or more mounting holes 110 can be positioned to correspond to the mounting bosses 180 of the cassette hold down 150.

The cassette hold down 150 includes a plurality of contact arms 160 with cassette contacts 162 and pod contacts 164. The cassette hold down 150 is configured to restrict movement of a wafer cassette 130 within the internal space 190. In particular, the cassette hold down 150 is configured to restrict vertical movement of the wafer cassette 130 within the internal space 190. The cassette hold down 150 is configured to apply pressure to the wafer cassette 130 at the cassette contacts 162 to restrict movement of the wafer cassette 130 within the pod 102. During normal transport, the pod contacts 164 are configured to be spaced apart from the pod 102. The pod contacts 164 are configured to be pushed into contact with the pod 102 by sudden movement of the wafer container 100 (e.g., a substantial shock event of the wafer container 100). The contact of the pod contacts 164 with the pod 102 is configured to limit the vertical movement of the wafer cassette 130 in the internal space 190. For example, the contact of the pod contacts 164 with the pod 102 is configured to stop further vertical movement of the wafer cassette 130 within the internal space 190.

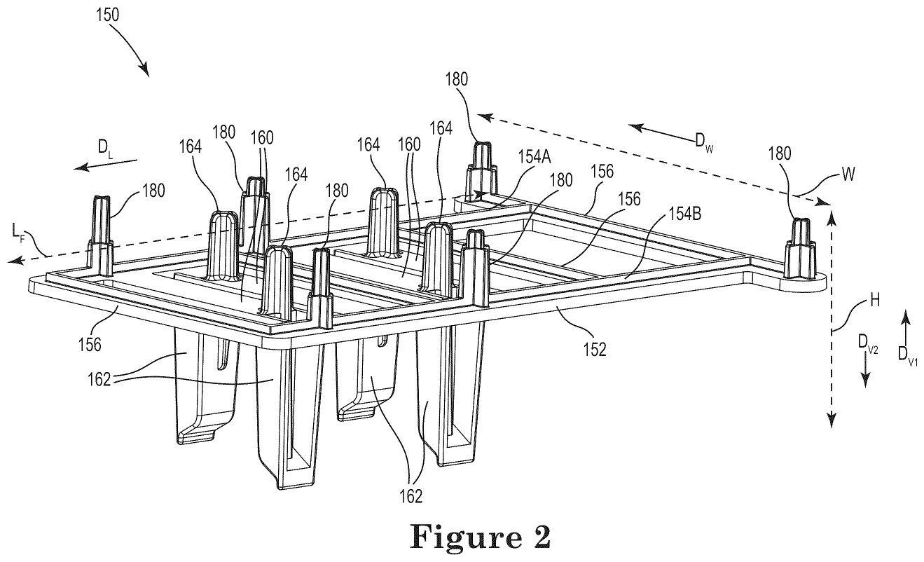

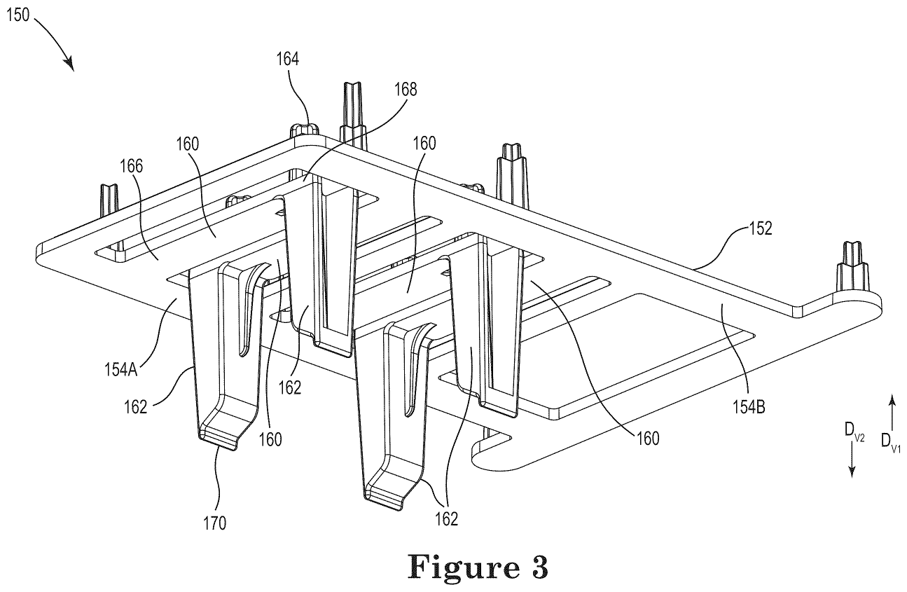

FIG. 2 shows a top perspective view of the cassette hold down 150, according to an embodiment. FIG. 3 shows a bottom perspective view of the cassette hold down 150, according to an embodiment. The cassette hold down 150 includes the frame 152, the contact arms 160, and the mounting bosses 180. The contact arms 160 include container the cassette contacts 162 and the pod contacts 164.

The frame 152 forms the body of cassette hold down 150. The frame 152 connects the other elements of cassette hold down 150. For example, the frame 152 connects the arms 160, which include the cassette contacts 162 and the pod contacts 164, and the mounting bosses 180.

Frame 152 can include one or more beam members that connect these elements. The frame 152 has a length direction D_{L}, a width direction D_{W}, and a height direction (e.g., first vertical direction D_{V1}, second vertical direction D_{V2}) that is perpendicular to the plane framed by the length direction D_{L} and the width direction D_{W}. The frame 152 can have a length L_{F} extending along the length direction D_{L}, a width W extending in the width direction D_{W}, and a height H extending in the height direction. As shown in the figures, the frame 152 can have a substantially planar shape.

The frame 152 can be formed by a plurality of beam members. For example, the frame 152 can include a pair of longitudinal members 154A, 154B and horizontal members 156 that connect the pair of longitudinal members 154A, 154B. The longitudinal members 154A, 154B each extend along a length L_{F} of the frame 152 (e.g., in the length direction D_{L}). The horizontal members 156 each extend along the width W of the frame 152 (e.g., in the width direction Dw).

The mounting bosses 180 are one or more vertical projections from the frame 152. The mounting bosses 180 extend in a vertical direction (e.g., vertical direction DV₁) from the first side of the frame 152. The mounting bosses 180 provided on an opposite side of the frame 152 from the cassette contacts 162. For example, the mounting bosses 180 extend from the upper side of the frame 152 in the first vertical direction D_{V1} (e.g., in the upward direction). The mounting bosses 180 include one or more features configured to engage with one or more engagement features provided on the pod 102 (e.g., engagement features provided on an inner side of the closed end 106 of the pod 102). The mounting bosses 180 are provided in locations corresponding to the relative positions of the engagement features of the pod 102. For example, the mounting bosses 180 can be projections with a plus-sign-shaped cross section that are sized to press-fit into mounting holes provided in corresponding locations on an inner side of the closed end 106 of the pod 102. It should be appreciated that the mounting bosses 180 in other embodiments can have any suitable shape or size to stably mount the cassette hold down 150 onto the pod 102 when the wafer container 100 is assembled.

As shown in FIG. 3, the contact arms 160 extend from the longitudinal members 154A, 154B. The contact arms 160 extend from the longitudinal members 154A, 154B of the frame 152. For example, the contact arms 160 can extend between the pair of longitudinal members 154A, 154B. Each of the contact arms 160 includes a fixed end 166 and a free end 168 opposite to the fixed end 166. The fixed end 166 is affixed to the frame 152. For each contact arm 160, a cassette contact 162 and a pod contact 164 each extend from the free end 168 of the respective contact arm 160. For each contact arm 160, the pod contact 164 extends from the free end 168 in a first vertical direction D_{V1} (e.g., in an upward direction from a first side of the frame 152). For example, each pod contact 164 extends in an upward direction from the top side of the frame 152. For each contact arm 160, the cassette contact 162 extends from the free end 168 in a second vertical direction D_{V2} from a second side of the frame 152. For example, the cassette contact 162 extends from the free end 168 in a downward direction from the bottom side of the frame 152.

The contact arms 160 are configured to be flexible relative to allow the free end 168 of the contact arms 160 to move independent from the frame 152. This allows for the frame 152 to remain in place (e.g., remain in its mounted position) while one or more of the contact arms 160 is pushed upwards by the wafer cassette 130. The contact arms 160 are pushed upwards when the wafer container 100 is assembled, such that the contact arms 160 apply a downward pressure on the wafer cassette 130 by the cassette contacts 162. The cassette contacts 162 are configured to contact the wafer cassette and apply downward pressure onto the wafer cassette 130. The downward pressure on the wafer container 100 is configured to restrict movement of the wafer cassette 130 within the internal space 190. In particular, the downward pressure on the wafer container 100 by the contact arms 160 is configured to restrict vertical movement (e.g., upward movement) of the wafer cassette 130 within in the internal space 190. For example, this downward pressure applied by the contact arms 160 is configured to keep the wafer cassette 130 in place during normal transport of the wafer container 100.

Each cassette contact 162 has an abutment surface 170 that is configured to contact the wafer cassette 130. The abutment surface 170 of each cassette contact 162 pushes against the top surface of the wafer cassette 130. The cantilever structure of the contact arm 160 results in a smaller initial downward pressure of the abutment surface 170 on the wafer cassette 130, in which the downward pressure applied by the arm increases as the wafer cassette 130 moves vertically upward within the internal space 190. As the wafer cassette 130 is moved vertically upwards, the flexion of each arm 160 increases causing each arm 160 to apply a greater downward force on the wafer cassette 130. The arms 160 applying a smaller initial downward force helps reduce particle generation between each abutment surface 170 and the wafer cassette 130.

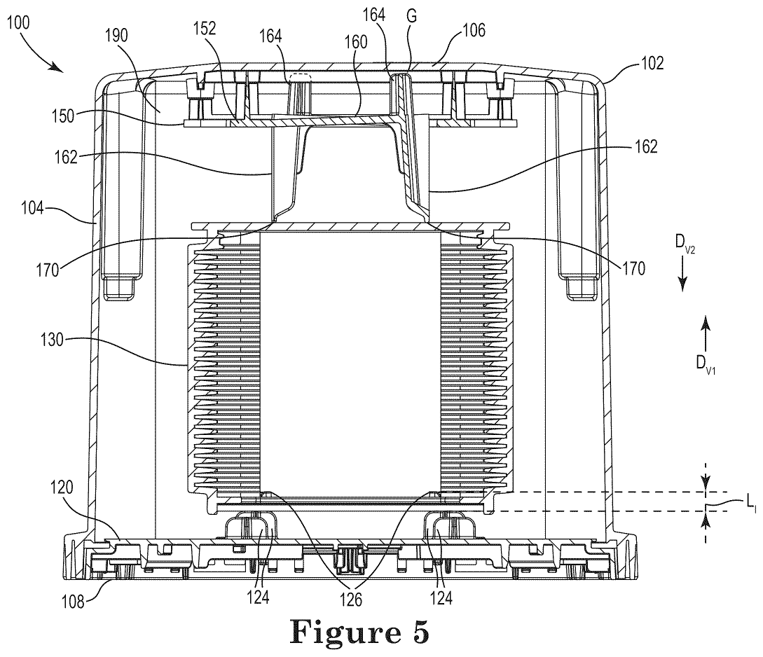

As shown in FIG. 3, the abutment surface 170 can be a linear abutment surface that provides a linear contact point in abutting the wafer cassette 130 (e.g., as shown in FIGS. 5-7) . A linear contact point between two surfaces is contact that is limited to a single line of contact between the two surfaces. For example, the linear contact point can limit contact between the cassette hold down 150 and the wafer cassette 130. Such limited contact helps prevent particle generation within the wafer container 100.

The cassette hold down 150 can include materials suitable for contact with or presence within a wafer container for semiconductor wafers. The cassette hold down 100 can include one or more polymeric materials. The cassette hold down 150 at the contact arms 160 is a material suitably flexible to allow bending of the contact arms 160 during assembly of the wafer container 100 and suitably elastic that the contact arms 160 apply a consistent downward force over the lifetime of the container 100. For example, the cassette hold down 150 at the frame 152 and at the arms 160 may be formed of, but not limited to, one or more of polycarbonate (PC), acrylonitrile butadiene styrene (ABS), polyether ether ketone (PEEK), polypropylene (PP), polystyrene (PS), and the like. Cassette hold down 150 at the cassette contacts 162 (e.g., providing the abutment surface 170) and at the pod contacts 164 (e.g., providing the surface that abuts the inner surface of the pod 102) can be made of a suitable material to provide relatively soft contact with the wafer cassette 130 to limit or prevent particle generation caused by contact of the contact arms 160 on the wafer cassette 130 and on pod 102. In an embodiment, the abutment surface 170 of each arm 160 may be formed of a thermoplastic. For example, each abutment surface 170 may be formed of, but not limited to, one or more of thermoplastic elastomer (TPE), thermoplastic polyurethane (TPU), and the like. In an embodiment, the cassette hold down 150 may be made of a single material or multiple materials.

FIG. 4A shows a bottom view of the pod 102 of the wafer container 100, according to an embodiment. FIG. 4B shows a bottom view of the cassette hold down 150 mounted to the pod 102, according to an embodiment.

As shown in FIG. 4A, the pod 102 includes mounting holes 110 for the cassette hold down 150. The mounting holes 110 can be provided on the closed end 106 of the pod 102. For example, the mounting holes 110 are provided on the inner side of the closed end 106 of the pod 102. The mounting holes 110 are positioned to correspond to the mounting bosses 180 of the cassette hold down 150. The cassette hold down 150 is mounted to the pod 102 by mating of the mounting bosses 180 to the mounting holes 110. For example, each mounting boss 180 is inserted into a corresponding mounting hole 110. For example, each mounting boss 180 friction fits into the corresponding mounting hole 110.

Referring to FIG. 4B, the contact arms 160 extend from the frame 152 in different directions. For example, the contact arms 160 include a first contact arm 160A that extends from the first longitudinal member 154A and a second contact arm 160B that extends from the second longitudinal member 154B. The first contact arm 160A and the second contact arm 160B are disposed side-by-side. The first contact arm 160A and the second contact arm 160B extend from the frame 152 in opposite directions. The free end 168 of the first contact arm 160A is located closer to second longitudinal member 154B than to the first longitudinal member 154A. The free end 168 of the second contact arm 160B is located closer to first longitudinal member 154A than to the second longitudinal member 154B.

The contact arms 160 extend side-by-side from the frame 152 (e.g., see FIG. 4B). Along the length L_{F} of the frame 152 (e.g., in the length direction D_{L}), the contact arms 160 can extend in alternating directions. The contact arms 160 each extending along the width W of the frame 152 (e.g., in the width direction D_{W}). The contact arms 160 each have a length L_{A} extending along the same direction (e.g., length extending in the width direction D_{W}). The length L_{A} is measured from the fixed end 166 to the free end 168 of each contact arm 160. For example, the length L_{A} of the contact arms 160 extends in the width direction D_{W} of the frame 152.

The contact arms 160 can also include a third contact arm 160C and a fourth contact arm 160D. The third and fourth contact arms 160C, 160D can extend from the frame 152 similar to the first and second contact arms 160A, 160B, respectively. For example, the third contact arm 160C can extend from the first longitudinal member 154A in the same direction as the first contact arm 160A, and the fourth contact arm 160D can extend from the first longitudinal member 154A in the same direction as the second contact arm 160B. In the illustrated embodiment, the cassette hold down 150 has four of the contact arms 160 for contacting the wafer cassette 130. It should be appreciated that the cassette hold down 150 in other embodiments may have a different number of contact arms 160. For example, the cassette hold down 150 in an embodiment has at least one contact arm 160. For example, the cassette hold down 150 in other embodiments may have two or more contact arms 160, four or more contact arms 160, or more than four contact arms 160.

FIG. 5 is a front sectional view of the wafer container 100, according to an embodiment. The sectional view in FIG. 5 is along the plane indicated in FIG. 4B. FIG. 5 shows the wafer container 100 when assembled. The wafer container 100 is assembled by closing the pod 102 mounted the cassette hold down 150 with the door 120 having the wafer cassette 130 disposed thereon. The pod 102 can be closed with the door 120 by lowering the pod 102 onto the door 120, by raising the door 120 to the pod 102, or by a combination thereof.

As shown in FIG. 5, the cassette hold down 150 is mounted to the pod 102 such that each of the contact arm 160 abuts the wafer cassette 130 in the assembled wafer container 100. The cassette contact 162 of each contact arm 160 abuts the wafer cassette 130 (e.g., abuts the top side of the wafer cassette 130). Each of the contact arms 160 applies downward pressure onto the wafer cassette 130 at the cassette contact 162. Downward pressure (e.g., pressure in direction D_{V2}) of the cassette contacts 162 of the contact arms 160 on the wafer cassette 130 restricts movement of the wafer cassette 130 within the internal space 190. In particular, the downward pressure on the wafer cassette 130 restricts vertical movement of the wafer cassette 130 within the internal space 190 (e.g., movement in the direction D_{V1}, upward movement).

For each contact arm 160, the downward pressure is applied by the cassette contact 162 disposed on the free end 168 of the contact arm 160. Each contact arm 160 is cantilever that extends from the frame 152. In the assembly of the wafer container 100, the disposing of the wafer cassette 130 in the internal space 190 of the pod 102 pushes and moves the contact arms 160 upwards (e.g., towards the closed end 106 of the pod 102) and tensions the contact arms 160. For example, the contact arms 160 are moved from a relaxed position (e.g., shown in FIGS. 1-3) to a tensioned position (e.g., shown in FIG. 5) during the assembly the wafer container 100. In particular, the closing of the pod 102 with the door 120 during assembly of the wafer container 100 inserts the wafer cassette 130 into the internal space 190 of the pod 102 and pushes the contact arms 160 upwards. The tensioned contact arms 160 in the assembled wafer container 100 apply the downward force on the wafer cassette 130.

As shown in FIG. 5, the cassette hold down 150 is mounted to the pod 102 such that the contact arms 160 are not in contact with the pod 102 when assembled. In particular, a gap G is provided between the pod contact 164 of each contact arm 160 and the pod 102 (e.g., between each pod contact 164 and the closed end 106 of the pod 102). The gap G is a gap measured in the first direction D_{V1} (e.g., vertical gap measured in the vertical direction, measured in the heigh direction D_{H}).

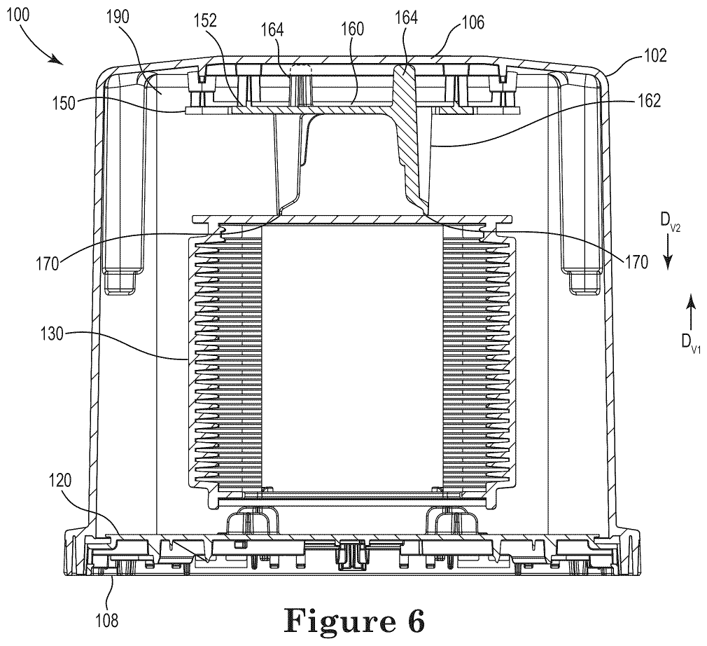

FIG. 6 shows the wafer container 100 when a significant shock event occurs, according to an embodiment. When a significant shock event of the wafer container 100 occurs, the wafer cassette 130 can be moved within the internal space 190 towards the closed end 106 of the pod 102 (e.g., vertically upwards). The shock event moves the wafer cassette 130 away from the door 120 towards the closed end 106 of the pod 102. In the illustrated example, the significant shock event is a shock event that applies upward force to wafer cassette 130 that is greater than the downward pressure of the cassette hold down 150 on the wafer cassette 130. When a significant shock event occurs, the wafer cassette 130 pushes the contact arms 160 towards closed end 106 of the pod 102 and the pod contacts 164 of the contact arms 160 into contact with the pod 102.

As shown in FIG. 6, the pod contacts 164 are pushed against an inner surface of the closed end 106 of the pod 102. For each contact arm 160, the abutting of the pod contact 164 against the pod 102 prevents further movement of the contact arm 160. The abutment of the pod contacts 164 prevents further upward movement of the contact arm 160 which stops further upward movement of the wafer cassette 130. The pod contacts 164 are configured to limit the upward movement of the wafer cassette 130 within the internal space 190. In each contact arm 160, the cassette contact 162 and the pod contact 164 are provided on opposite sides of the free end 168 of the contact arm 160, such that the cassette contact 162 and the pod contact 164 in combination form a rigid structure at the free end 168 of the contact arm 160. When the pod contacts 164 are pushed against the pod 102, this rigid structure formed by the contacts 162 in each contact arm acts as a brace that stops upward movement (e.g., in the direction DV₁) of the wafer cassette 130. The contact arms 160 of the cassette hold down 150 can both reduce vertical movement of the wafer cassette 130 within the internal space 190 (via the downward force on the wafer cassette 130) and limit the vertical movement of the of the wafer cassette 130 within the internal space 190 (via the pod contacts 164 abutting the pod 102).

The supports 124 for the wafer cassette 130 include guides 126 that interface with the wafer cassette 130 and prevent lateral movement of the wafer cassette 130 in the internal space 190. For example, during processing of wafers, the wafer cassette 130 can be removed from the door 120 by lifting the wafer cassette 130 above the guides 126. The guides 126 have an interface length L_{I}. For example, the interface length L₁ can be length of the guides 126 in the first direction D_{V1} (e.g., a height of the guides 126). The wafer cassette 130 remains interfaced with the guides 126 until the wafer cassette 130 is moved in the first direction D_{V1} (e.g., raised, lifted up off the door 120) by at least the interface length L_{I}. The gap G for each of the pod contacts 164 is configured to be less than the interface length L_{I} (i.e., length of gap G in the vertical direction <interface length L_{I})_{.} The pod contacts 164 are configured to contact the pod 102 and prevent disengagement of the wafer cassette 130 from the guides 126. The pod contacts 164 are configured to prevent movement of the wafer cassette 130 in the internal space 190 that would disengage the wafer cassette 130 from the guides 126. This limits the vertical movement of the wafer cassette 130 in the internal space 190 when a significant shock of the wafer container 100 occurs.

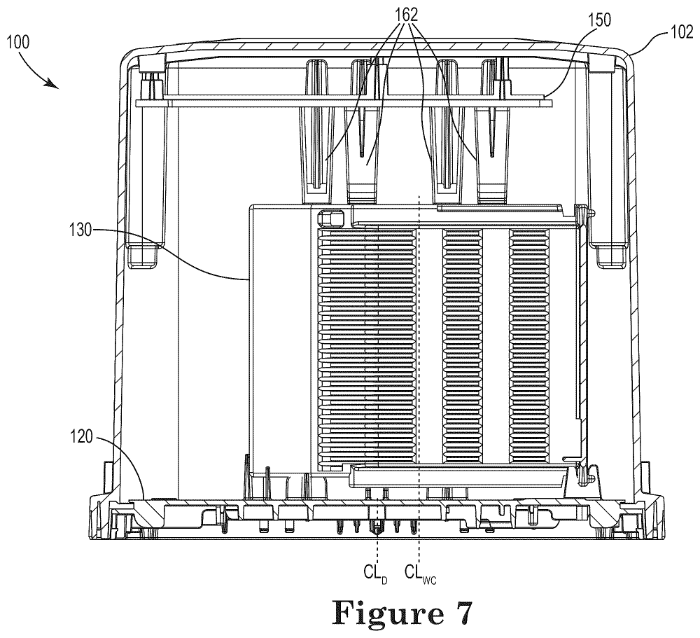

FIG. 7 shows a side sectional view of the wafer container 100, according to an embodiment. The view in FIG. 7 is along the plane indicated in FIG. 4B.

The cassette hold down 150 applies downward force on the wafer cassette 130 as previously discussed. As shown in FIG. 7, the wafer cassette 130 is disposed off center on the door 120 (e.g., the wafer cassette 130 is not centered on the door 120). For example, the wafer cassette 130 is disposed on the door 120 such that the centerline CL_{WC} of the wafer cassette 130 is offset from the centerline CL_{D} of the door 120 (e.g., a centerline CL_{WC} of wafer cassette 130 is forward of the centerline CL_{D} of the door 120). A centerline of a component is disposed equidistant from the sides of said component (e.g., equidistance between the front and rear sides and equidistance between the left and right sides). The wafer cassette 130 is configured have a front of the wafer cassette 130 disposed near a front edge of the door 120. For example, the wafer cassette 130 is disposed to have its front at the same position as a full-sized wafer cassette disposed in the pod 102.

The cassette hold down 150 is configured to apply downward force on the wafer cassette 130 that is centered on the wafer cassette 130. For example, the total downward force applied on the wafer cassette by the cassette contacts 162 is at or about the centerline CL_{WC} of the wafer cassette 130. Downward force being applied on the wafer cassette 130 in a centered manner can reduce movement of the wafer cassette 130 within the internal space 190 while avoiding tipping of the wafer cassette 130. For example, a downward force on the wafer cassette 130 that is at the center of the door 120 would apply an un-centered force to the wafer cassette 130 which can cause tipping of the wafer cassette 130 within the wafer container 100. For example, the downward force on the wafer cassette 130 can be at or about centered by having an arm apply force at equidistant portions to the centerline CL_{WC} of the wafer cassette 130 (e.g., having four arms applying force at four quadrants on equidistant front/back/right/left sections as defined by the centerline CL_{WC} of the wafer cassette 130). The downward force of the wafer cassette 130 can be configured to apply downward force at points closer to the sides of the wafer cassette 130 than to the centerline CL_{WC} of the wafer cassette 130.

In an embodiment, the wafer container 100 may be configured for the wafer cassette 130 to be disposed in a centered position on the door 120. For example, the wafer cassette 130 in the centered position has the centerline CL_{WC} of the wafer cassette 130 at the same position as the centerline CL_{D} of the door 120 (e.g., centerline CL_{WC} and centerline CL_{D} overlapping in the side view of FIG. 7). The cassette hold down 150 can be used to similarly apply a downward force on a centered wafer cassette 130.

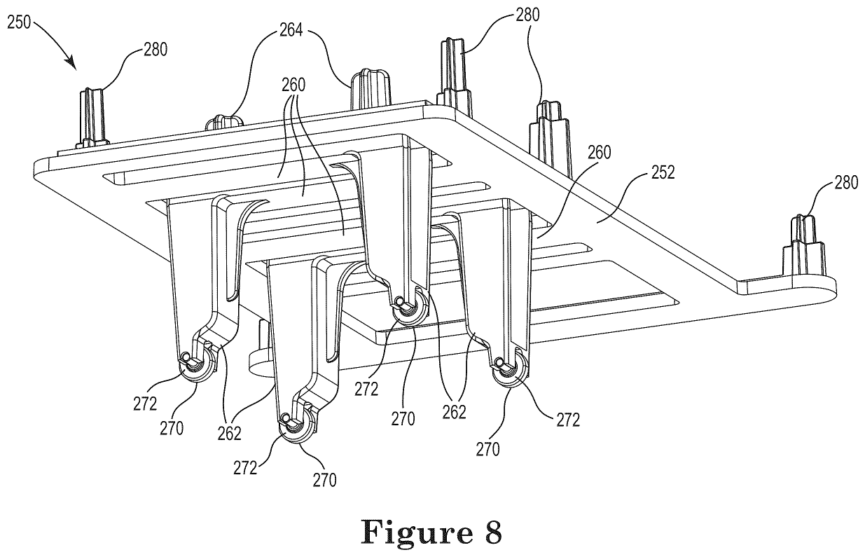

FIG. 8 is a bottom perspective view of another embodiment of a cassette hold down 250. The cassette hold down 250 in FIG. 8 can have similar features as discussed for the cassette hold down 150 in FIGS. 1-3, except for the cassette contacts. For example, the cassette hold down 250 includes a frame 252, mounting bosses 280 that extend from the frame 252, contact arms 260 that each extend from the frame 252 and include a cassette contact 262 and a pod contact 264. In an assembled wafer container, the cassette hold down 250 can mounts to a pod of the wafer container and applies a downward force on wafer cassette via the cassette contacts 262 and the pod contacts 264 are configured to contact the pod to limit movement of the wafer cassette (e.g., in a similar manner as discussed for the cassette hold down 150 in FIGS. 5-7) . It should be appreciated that the cassette hold down 250 may have features as similarly discussed for the cassette hold down 150 in FIGS. 1-3 and 4B-7 .

Each cassette contact 262 has an abutment surface 270 that is configured to contact the wafer cassette (e.g., wafer cassette 130 in FIGS. 5-7). The abutment surface 270 of each cassette contacts 262 pushes against the top surface of the wafer cassette (e.g., pushes downward on the top surface of the wafer cassette). As shown in FIG. 8, the cassette contact 262 of each contact arm 260 includes a wheel 272. Wheel 272 is rotatably affixed on the contact arm 260. The wheel 272 is configured to be rotatable relative to the rest of the contact arm 260. The wheel 272 is also rotatable relative to the frame 252. In each contact arm 260, the wheel 272 provides the abutment surface 270. The bottom side of the wheel 272 provides the abutment surface 270 of each contact arm 260 (e.g., the wheel 272 includes the abutment surface 270). The abutment surface 270 of each contact arm 260 is configured to provide a contact point with the wafer cassette in the assembled wafer container. The wheel 272 of each contact arm 260 is configured to provide the contact point of the cassette contact 262 on a wafer cassette.

The abutment surface 270 provided by each wheel 272 is a linear abutment surface. For example, the linear abutment extends parallel to the axis of rotation of the wheel 272. In an assembled wafer container, the linear abutment surface of the wheel 272 is configured to provide a linear contact point in abutting the wafer cassette in the assembled wafer container.

### Aspects

Any of Aspects 1-13 may be combined with any of Aspects 14-20.

Aspect 1. A cassette hold down, comprising: a frame; and a plurality of contact arms extending from the frame, the contact arms including a first contact arm and a second contact arm that extend in different directions from the frame, each of the contact arms including: a fixed end affixed to the frame, a free end opposite to the fixed end, a pod contact extending from the free end in a first vertical direction from a first side of the frame, and a cassette contact extending from the free end in a second vertical direction from a second side of the frame opposite the first side.

Aspect 2. The cassette hold down of Aspect 1, wherein the frame includes a pair of longitudinal members extending along a length of the frame, the contact arms extending between the pair of longitudinal members.

Aspect 3. The cassette hold down of Aspect 2, wherein the first contact arm extends from a first longitudinal member of the pair of longitudinal members, and the second contact arm extends from a second longitudinal member of the pair of longitudinal members.

Aspect 4. The cassette hold down of Aspect 3, wherein the free end of the first contact arm is located closer to second longitudinal member than the first longitudinal member, and the free end of the second contact arm is located closer to the first longitudinal member than the second longitudinal member.

Aspect 5. The cassette hold down of any one of Aspects 1-4, wherein the contact arms are configured to be flexible allowing the free end of each of the contact arms to move independently from the frame.

Aspect 6. The cassette hold down of any one of Aspects 1-5, wherein the contact arms extend side-by-side from the frame, the contact arms extending in alternating directions along a length of the frame.

Aspect 7. The cassette hold down of any one of Aspects 1-6, wherein the different directions in which the first contact arm and the second contact arm extend from the frame are opposite directions.

Aspect 8. The cassette hold down of any one of Aspects 1-7, wherein the contact arms including a third contact arm and a fourth contact arm that extend from the frame in the same different directions as the first contact arm and the second contact arm, respectively.

Aspect 9. The cassette hold down of any one of Aspects 1-8, wherein the plurality of contact arms includes at least four contact arms.

Aspect 10. The cassette hold down of any one of Aspects 1-9, further comprising: a plurality of mounting bosses, each of the mounting bosses extending from the frame in the first vertical direction from the first side of the frame.

Aspect 11. The cassette hold down of Aspect 10, wherein the mounting bosses are configured to mount the frame to an inside of a pod of a wafer container such that a gap is provided between the cassette contact of each of the contact arms and the inside of the wafer container.

Aspect 12. The cassette hold down of any one of Aspects 1-11, wherein the cassette contact of each of the contact arms includes a linear abutment surface configured to provide a linear contact point in abutting a wafer cassette.

Aspect 13. The cassette hold down of Aspect 12, wherein the cassette contact of each of the contact arms includes a wheel providing the linear abutment surface.

Aspect 14. A wafer container, comprising: a pod including one or more side walls, a closed end, an internal space defined by the one or more side walls and the closed end, and an open end; a door, the door configured to close the open end of the pod; a wafer cassette; and a cassette hold down including a frame and a plurality of contact arms extending from the frame, the contact arms including a first contact arm and a second contact arm that extend in different directions from the frame, each of the contact arms including: a fixed end affixed to the frame, and a free end opposite to the fixed end, a pod contact extending from the free end in a first vertical direction from a first side of the frame, and a cassette contact extending from the free end in a second vertical direction from a second side of the frame opposite the first side, wherein when the wafer cassette and the cassette hold down are located in the internal space and the door is closing the open end, the cassette contact of each of the contact arms abuts the wafer cassette.

Aspect 15. The wafer container of Aspect 14, wherein when the wafer cassette and the cassette hold down are located in the internal space and the door is closing the open end, each of the contact arms has the pod contact spaced apart from an inner surface of the pod.

Aspect 16. The wafer container of Aspect 15, wherein the contact arms are configured to be flexible such that upward movement of the cassette pushes the pod contact of each of the contact arms against the inner surface of the pod and the contact arms limit the upward movement of the cassette within the internal space.

Aspect 17. The wafer container of any one of Aspects 14-16, wherein the door includes supports for holding the wafer cassette within the internal space, the supports configured to restrict lateral movement of the wafer cassette while allowing vertical movement of the wafer cassette.

Aspect 18. The wafer container of any one of Aspects 14-17, further comprising: a plurality of mounting holes disposed in an inner surface of the pod, the cassette hold down including a plurality of mounting bosses that each extend in the first vertical direction from the first side of the frame, and the mounting bosses configured to be disposed in the plurality of mounting holes to mount the cassette hold down to the inner surface of the pod.

Aspect 19. The wafer container of Aspect 18, wherein when the cassette hold is mounted to the inner surface of the pod, the pod contact of each of the contact arms is spaced apart from the inner surface of the pod.

The examples disclosed in this application are to be considered in all respects as illustrative and not limitative. In an embodiment, “connects” and “connecting” as described above may refer to “directly connecting”. In an embodiment, “contacts” and “contacting” as described above may refer to “directly contacting”. The scope of the invention is indicated by the appended claims rather than by the foregoing description; and all changes which come within the meaning and range of equivalency of the claims are intended to be embraced therein.

What is claimed is:

1. A cassette hold down, comprising:
a frame; and
a plurality of contact arms extending from the frame, the contact arms including a first contact arm and a second contact arm that extend in different directions from the frame, each of the contact arms including:
a fixed end affixed to the frame,
a free end opposite to the fixed end,
a pod contact extending from the free end in a first vertical direction from a first side of the frame, and
a cassette contact extending from the free end in a second vertical direction from a second side of the frame opposite the first side.

2. The cassette hold down of claim 1, wherein the frame includes a pair of longitudinal members extending along a length of the frame, the contact arms each extending between the pair of longitudinal members.

3. The cassette hold down of claim 2, wherein the first contact arm extends from a first longitudinal member of the pair of longitudinal members, and the second contact arm extends from a second longitudinal member of the pair of longitudinal members.

4. The cassette hold down of claim 3, wherein
the free end of the first contact arm is located closer to second longitudinal member than the first longitudinal member, and
the free end of the second contact arm is located closer to the first longitudinal member than the second longitudinal member.

5. The cassette hold down of claim 1, wherein the contact arms are configured to be flexible allowing the free end of each of the contact arms to move independently from the frame.

6. The cassette hold down of claim 1, wherein the contact arms extend side-by-side from the frame, the contact arms extending in alternating directions along a length of the frame.

7. The cassette hold down of claim 1, wherein the different directions in which the first contact arm and the second contact arm extend from the frame are opposite directions.

8. The cassette hold down of claim 1, wherein the contact arms including a third contact arm and a fourth contact arm that extend from the frame in the same different directions as the first contact arm and the second contact arm, respectively.

9. The cassette hold down of claim 1, wherein the plurality of contact arms includes at least four contact arms.

10. The cassette hold down of claim 1, further comprising:
a plurality of mounting bosses, each of the mounting bosses extending from the frame in the first vertical direction from the first side of the frame.

11. The cassette hold down of claim 10, wherein the mounting bosses are configured to mount the frame to an inside of a pod of a wafer container such that a gap is provided between the cassette contact of each of the contact arms and the inside of the wafer container.

12. The cassette hold down of claim 1, wherein the cassette contact of each of the contact arms includes a linear abutment surface configured to provide a linear contact point in abutting a wafer cassette.

13. The cassette hold down of claim 12, wherein the cassette contact of each of the contact arms includes a wheel providing the linear abutment surface.

14. A wafer container, comprising:
a pod including one or more side walls, a closed end, an internal space defined by the one or more side walls and the closed end, and an open end;
a door, the door configured to close the open end of the pod;
a wafer cassette; and
a cassette hold down including a frame and a plurality of contact arms extending from the frame, the contact arms including a first contact arm and a second contact arm that extend in different directions from the frame, each of the contact arms including:
a fixed end affixed to the frame,
a free end opposite to the fixed end,
a pod contact extending from the free end in a first vertical direction from a first side of the frame, and
a cassette contact extending from the free end in a second vertical direction from a second side of the frame opposite the first side,
wherein when the wafer cassette and the cassette hold down are located in the internal space and the door is closing the open end, the cassette contact of each of the contact arms abuts the wafer cassette.

15. The wafer container of claim 14, wherein when the wafer cassette and the cassette hold down are located in the internal space and the door is closing the open end, each of the contact arms has the pod contact spaced apart from an inner surface of the pod.

16. The wafer container of claim 15, wherein the contact arms are configured to be flexible such that upward movement of the wafer cassette pushes the pod contact of each of the contact arms against the inner surface of the pod and the contact arms limit the upward movement of the cassette within the internal space.

17. The wafer container of claim 14, wherein the door includes supports for holding the wafer cassette within the internal space, the supports configured to restrict lateral movement of the wafer cassette while allowing vertical movement of the wafer cassette.

18. The wafer container of claim 14, further comprising:
a plurality of mounting holes disposed in an inner surface of the pod, and
the cassette hold down including a plurality of mounting bosses that each extend in the first vertical direction from the first side of the frame, the mounting bosses configured to be disposed in the plurality of mounting holes to mount the cassette hold down to the inner surface of the pod.

19. The wafer container of claim 18, wherein when the cassette hold is mounted to the inner surface of the pod, the pod contact of each of the contact arms is spaced apart from the inner surface of the pod.
